(19) United States
(12) Patent Application Publication
(10) Pub. No.: US 2025/0374525 A1
(43) Pub. Date: Dec. 4, 2025

(54) MICROELECTRONIC DEVICES COMPRISING ASYMMETRIC WORD LINES, AND RELATED METHODS AND ELECTRONIC SYSTEMS

(71) Applicant: Micron Technology, Inc., Boise, ID (US)

(72) Inventors: Hongmei Wang, Boise, ID (US); Litao Yang, Boise, ID (US); Don Koun Lee, Boise, ID (US); Yan Li, Boise, ID (US); Song Guo, Boise, ID (US); Anthony J. Kanago, Boise, ID (US); Haitao Liu, Boise, ID (US)

(21) Appl. No.: 19/195,346

(22) Filed: Apr. 30, 2025

Related U.S. Application Data
(60) Provisional application No. 63/654,601, filed on May 31, 2024.

(51) Int. Cl. H10B 12/00

(52) U.S. Cl. CPC H10B 12/36; H10B 12/056

(57) ABSTRACT

A microelectronic device comprises a memory cell array comprising memory cells. At least one of the memory cells comprises active areas and shallow trench isolation structures adjacent to a base material and fins extending from the base material and adjacent to the active areas. A gate dielectric material is between adjacent fins and a word line material is over the gate dielectric material. The word line material extends different depths between adjacent fins to form an asymmetric word line. The asymmetric word line extends a first depth between some adjacent fins and extends a second depth between other adjacent fins. Active word lines and passing word lines are adjacent to the asymmetric word line. Related electronic systems and methods are also disclosed.

### CROSS-REFERENCE TO RELATED APPLICATION

This application claims the benefit under 35 U.S.C. § 119 (e) of U.S. Provisional Patent Application Ser. No. 63/654,601, filed May 31, 2024, the disclosure of which is hereby incorporated herein in its entirety by this reference.

### TECHNICAL FIELD

Embodiments disclosed herein relate to the field of microelectronic device design and fabrication. More particularly, embodiments of the disclosure relate to microelectronic devices including asymmetric word lines, active word lines, and passing word lines, and to related methods and systems.

### BACKGROUND

Conventional volatile memory cells, such as dynamic random-access memory (DRAM) cells, may include a memory storage element and a transistor. The memory storage element may, for example, include a capacitor (e.g., sometimes referred to as a “cell capacitor” or a “storage capacitor”) configured to store a logical state (e.g., a binary vale of either a “0” or a “1”) defined by the stored charge in the capacitor. The transistor conventionally includes a channel region between a pair of source/drain regions and further includes a gate configured to electrically connect the source/drain regions to one another through the channel region. The channel region conventionally includes a semiconductor material, such as silicon.

To charge, discharge, read, or recharge the capacitor, the transistor may be selectively turned to an “on” state, in which current flows between the source region and the drain region through the channel region of the transistor. Application of a voltage greater than a threshold voltage (Vₜ) to the gate induces an inversion layer in the channel region, inducing a current flow between the drain region and the source region. The transistor may be selectively turned to an “off” state, in which the flow of current is substantially stopped.

In the off state, it is desirable for the capacitor associated with the transistor to retain a stored charge, without change (e.g., leakage thereof), through the transistor. However, conventional volatile memory cells may exhibit discharges of current over time and a resulting loss in stored charge. Therefore, even in the “off” state where the source region and the drain region of the associated transistor are electrically isolated (e.g., when an inversion layer is not present in the channel region) and the memory cell is unselected (e.g., not selected), current may leak from the capacitor through the transistor. This off-state current is referred to in the art as sub-threshold leakage current. The undesirable leakage of charge from the capacitor may call for the capacitor to be constantly refreshed (e.g., recharged) to maintain the logic state of the memory cell.

It is desirable to reduce an amount that an unselected memory cell is disturbed when a voltage is applied to a passing word line (e.g., a word line that is not electrically coupled to the unselected memory cell, but located proximate (e.g., adjacent) to the unselected memory cell). In some instances, application of a voltage to a passing word line adjacent to an unselected memory cell may induce leakage of current or charge from the capacitor associated with the unselected memory cell through the drain of the unselected memory cell. The leakage may call for an increased refresh rate of the unselected memory cell, which may negatively affect performance of a microelectronic device containing the memory cell. For example, when a row (e.g., a word line) is repeatedly activated and refreshed, noise may be injected into the adjacent row (e.g., a victim row), such that data corruption may occur in one or more memory cells in the victim row. The repeated activation and refreshing of the row are referred to as a so-called “row hammer” effect. A so-called “row hammer event” occurs when a refresh command is executed to refresh word lines that are adjacent to a hammered word line. A particular word line is “hammered” when it is accessed via memory access operations, such as an active command, in a manner that potentially leads to data errors in adjacent word lines. Leakage and parasitic currents caused by the hammering of a row may cause data corruption in a non-accessed physically adjacent row (e.g., the victim row). The row hammer effect may increase in frequency and/or severity as the spacing between adjacent features decreases. For example, row hammer may become especially pronounced as the feature size of a microelectronic device falls below about 18 nm.

### BRIEF DESCRIPTION OF THE DRAWINGS

FIG. 1 is a simplified, top-down view of a microelectronic structure in accordance with embodiments of the disclosure.

FIGS. 2A through 2D and 2F are simplified cross-sectional views illustrating a method of forming the microelectronic structure of FIG. 1.

FIG. 2E is a simplified, top-down view of the microelectronic structure of FIG. 2D.

FIG. 3 is a block diagram of an electronic system in accordance with embodiments of the disclosure.

FIG. 4 is a block diagram of a processor-based system, in accordance with embodiments of the disclosure.

### DETAILED DESCRIPTION

A microelectronic structure of an apparatus (e.g., an electronic device, a microelectronic device, a memory device) that includes active areas (e.g., memory cells), asymmetric word lines, active word lines, and passing word lines is disclosed. The passing word lines may be vertically adjacent to a memory cell, and the active word lines may extend horizontally between the passing word lines. The asymmetric word lines have a shallower depth in passing word line areas of the electronic device than in active word line areas of the electronic device. This configuration of the word lines may reduce leakage from a storage device (e.g., a capacitor) comprising one of the active areas during a so-called “off” state when an associated memory cell is not selected. The reduction in the charge leakage from the storage device may improve performance of the electronic device, such as by increasing the amount of time between refresh operations of the memory cells associated with the storage devices. Thus, the electronic device including the microelectronic structure according to embodiments of the disclosure may utilize less power and operate at higher speeds compared to conventional devices.

The following description provides specific details, such as material types, material thicknesses, and process conditions in order to provide a thorough description of embodiments described herein. However, a person of ordinary skill in the art would understand that the embodiments of the disclosure may be practiced without employing these specific details. Indeed, the embodiments of the disclosure may be practiced in conjunction with conventional electronic device fabrication techniques employed in the industry. In addition, the description provided below does not form a complete process flow for manufacturing a device (e.g., an electronic device, a microelectronic device, a memory device, such as DRAM memory device). The structures described below do not form a complete electronic device. Only those process acts and structures necessary to understand the embodiments of the disclosure are described in detail below. Additional acts to form a complete device from the structures may be performed by conventional fabrication techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only and are not meant to be actual views of any particular material, component, structure, device, apparatus, or system. Variations from the shapes depicted in the drawings as a result, for example, of manufacturing techniques and/or tolerances, are to be expected. Thus, embodiments described and illustrated herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the drawings are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the drawings. For example, if materials in the drawings are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “configured” refers to a size, shape, material composition, and arrangement of one or more of at least one structure and at least one apparatus facilitating operation of one or more of the structure and the apparatus in a pre-determined way.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Stated another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional dynamic random-access memory (DRAM); conventional non-volatile memory, such as conventional NAND memory), but also includes an application specific integrated circuit (ASIC) (e.g., a system on a chip (SoC)), an electronic device combining logic and memory, or a graphics processing unit (GPU) incorporating memory.

As used herein, the term “conductive material” means and includes an electrically conductive material. The conductive material may include one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, an “insulative structure” means and includes a structure formed of and including at least one insulative material.

As used herein, the term “selectively etchable” means and includes a material that exhibits a greater etch rate responsive to exposure to a given etch chemistry and/or process conditions relative to another material exposed to the same etch chemistry and/or process conditions. For example, the selectively etchable material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the phrase “coupled to” refers to structures operatively connected with each other, such as electrically connected through a direct ohmic connection or through an indirect connection (e.g., via another structure).

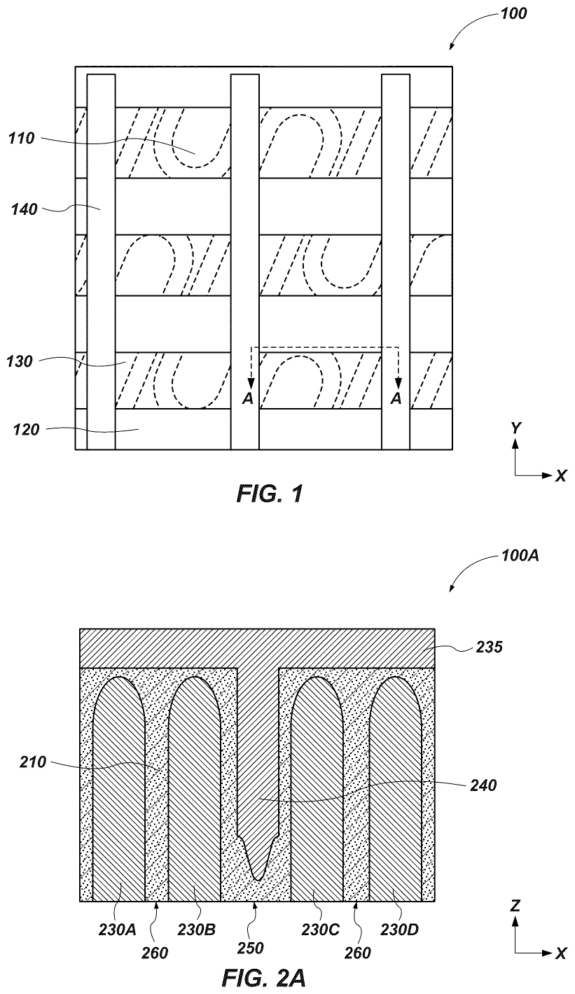

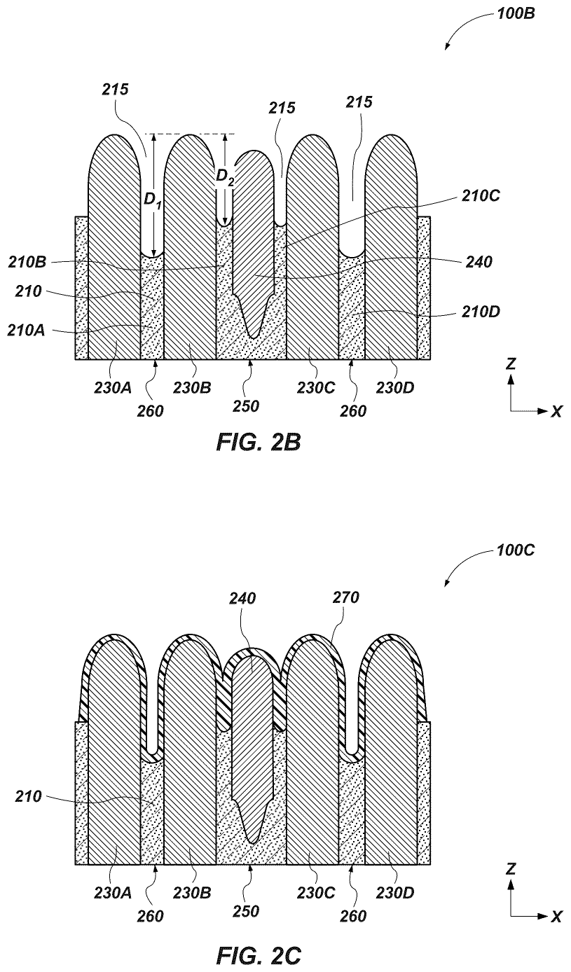

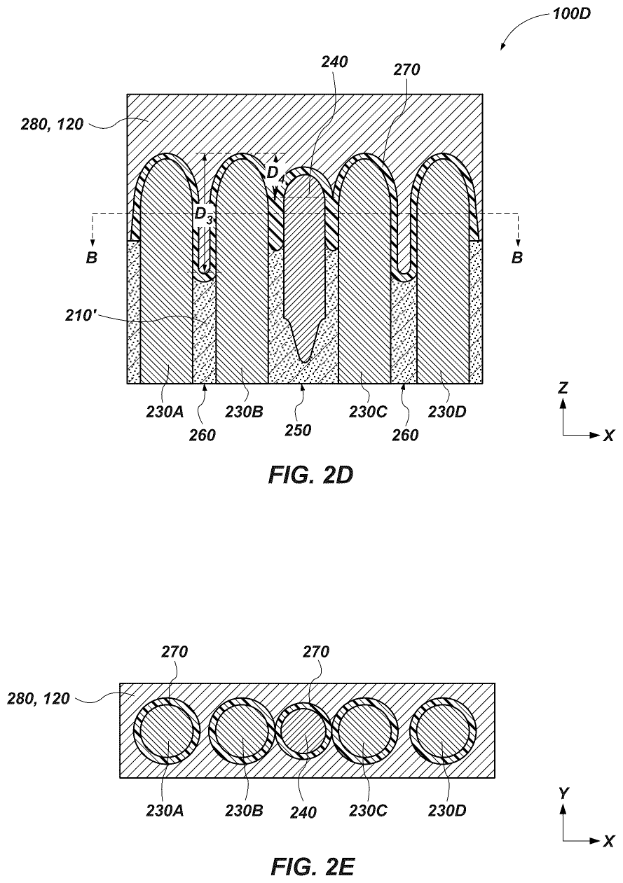

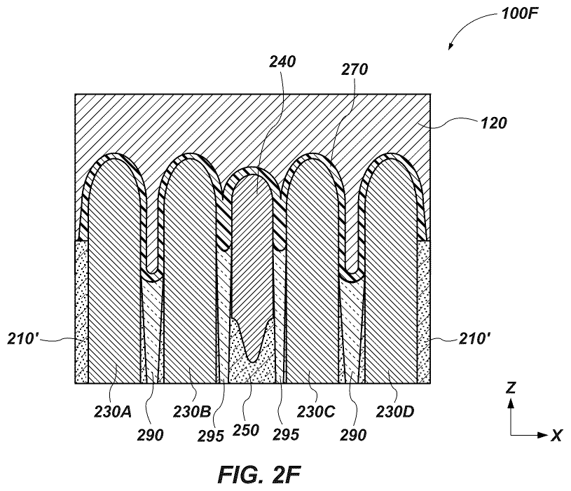

FIG. 1 is a simplified top-down view illustrating a microelectronic structure 100 (e.g., an electronic device, a microelectronic device, a memory device, such as a DRAM device) in accordance with embodiments of the disclosure. FIGS. 2A through 2D and 2F are simplified partial cross-sectional views of the microelectronic structure 100 of FIG. 1 at the processing stage shown in FIG. 1, where line A-A corresponds to the cross-sections of the microelectronic structure 100 depicted in FIGS. 2A through 2D and 2F. The microelectronic structure 100 includes asymmetric word lines 120, active word lines, and passing word lines.

With reference to FIG. 1, the microelectronic structure 100 may include active areas 110, asymmetric word lines 120 (e.g., memory device word lines) vertically overlying the active areas 110, fins 130 vertically overlying the active areas 110, and digit lines 140 vertically overlying the word lines 120. The microelectronic structure 100 may be a memory cell array of the electronic device (e.g., the memory device, such as a DRAM memory device). The word lines 120 may be oriented approximately perpendicular to the digit lines 140. The perpendicular arrangement of the word lines 120 and the digit lines 140 allows for a select active area (e.g., a select memory cell of the memory cell array) to be selected and written to or read from during operation of the electronic device that includes the memory cell array. The active areas 110 includes active circuitry and memory cells (e.g., arrays of memory cells). The active areas 110 may exhibit a substantially elliptical shape, a rectangular shape, or another shape, as best shown in the top-down view in FIG. 1. In some embodiments, the active areas 110 have an elliptical shape. Individual active areas 110 have a long axis (e.g., in a horizontal direction) that may be horizontally angled relative to the lengths (e.g., in the Y-direction) of the digit lines 140. By way of non-limiting example, the long axes of the individual active areas 110 and the lengths of the digit lines 140 form horizontal angles of from approximately 14 degrees to approximately 28 degrees, such as from approximately 17 degrees to approximately 25 degrees, such as from approximately 20 degrees to approximately 22 degrees. In some embodiments, the long axes of the individual active areas 110 and the lengths of the digit lines 140 form horizontal angles of approximately 21 degrees.

The microelectronic structure 100 may include a base material (not shown) below (e.g., in the Z-direction) the active areas 110, the asymmetric word lines 120, the fins 130, and the digit lines 140. The base material may be formed of and include a semiconductive material, such as a silicon material. The base material may include a semiconductor substrate, a base semiconductor material on a supporting substrate, or a semiconductor substrate having one or more materials, structures, or regions formed thereon. The base material may include one or more materials associated with integrated circuitry fabrication. Such materials may include, for example, one or more of refractory metals, barrier materials, diffusion materials, and insulative materials. The base material may include, for example, complementary metal oxide semiconductor (CMOS) structures, or other semiconductor structures. The base material may be a conventional silicon substrate or other bulk substrate including a semiconductive material. The base material may be doped or undoped. When reference is made to a “base material” in the following description, previous process stages may have been utilized to form material, regions, or junctions in the base semiconductor structure or foundation. The fins 130 may be formed of and include the base material. The fins 130 may include one or more dopants. One of the fins 130 may comprise a source region of a transistor and one of the fins 130 may comprise a drain region of a transistor. The fins 130 may be in electrical communication with a storage device (not shown) (e.g., a memory storage device, such as a capacitor).

The asymmetric word lines 120 and digit lines 140 may be formed of and include a conductive material. The word lines 120 and digit lines 140 may be formed of the same conductive material as one another or may be formed of different conductive materials. The word lines 120 and digit lines 140 may be electrically coupled to one another and the word lines 120 may be electrically coupled to corresponding memory cells of the active areas 110. The word lines 120 may also be electrically coupled to active word lines (AWLs) 290 (see FIG. 2F) and passing word lines (PWLs) 295 (see FIG. 2F), with the PWLs laterally adjacent to the AWLs. Shallow trench isolation (STI) structures 210′ isolate the AWLs 290 and the PWLs 295 from the fins 130. The word lines 120 exhibit, in cross-section, a relatively deeper depth proximal to the AWLs and a relatively shallower depth proximal to the PWLs (see, for example, word lines 120 in FIG. 2D). The word lines 120 extend different depths into an active word line area 260 (see FIG. 2A) of the microelectronic structure 100 relative to a passing word line area 250 (see FIG. 2A) of the microelectronic structure 100. The word lines 120 are, therefore, asymmetric in that the depths of the word lines 120 in the active word line areas 260 and the passing word line areas 250 are different. The word lines 120 (e.g., asymmetric word lines 120) extend deeper into the active word line areas 260 than into the passing word line areas 250. The AWLs 290 may ultimately be formed in the active word line area 260 and the PWLs 295 (see FIG. 2F) may ultimately be formed in the passing word line area 250. In contrast, in conventional microelectronic devices, the word lines have the same AWL depth and PWL depth or the PWL depth is deeper than the AWL depth.

FIGS. 2A through 2D are cross-sectional views of microelectronic structures 100A, 100B, 100C, 100D at various processing stages prior to the processing stage of the microelectronic structure 100 shown in FIGS. 1 and 2F, where the line A-A of FIG. 1 corresponds to the cross-section of the microelectronic structures 100A-100D depicted in FIGS. 2A through 2D and 2F. FIG. 2E is a top down view of the microelectronic structure 100D along the line B-B of FIG. 2D. For simplicity and convenience, the AWLs 290 and the PWLs 295 are omitted in the processing stages of FIGS. 2A through 2D and are shown in FIG. 2F.

Referring to FIG. 2A, the microelectronic structure 100 may comprise a first material 210 from which the STI structures 210′ are ultimately formed and fins 230, with the STI structures 210′ separating (e.g., in the X-direction) adjacent fins 230. Upper surfaces of the fins 230 are substantially coplanar with one another. The first material 210 and fins 230 may be formed by conventional techniques. The fins 230 are formed of the base material and include fins 230A, 230B, 230C, 230D. While four fins 230 are shown in FIG. 2A, additional numbers of fins 230 may be present. The first material 210 separates laterally adjacent fins 230 from one another. A second material 235 may overlic the first material 210 and the fins 230, with a portion 240 of the second material 235 extending (e.g., in the Z-direction) in an area between two neighboring fins 230 (e.g., fins 230B, 230C). The portion 240 of the second material 235 may extend into the passing word line area 250. The second material 235 may be an insulative material. Although a particular spacing between adjacent fins 230 is illustrated in FIG. 2A, the disclosure is not so limited. The spacing between the fins 230 may be different than (e.g., greater than, less than) that illustrated. The fins 230 may be uniformly spaced apart or the spacing between the fins 230B, 230C may be different than the spacing between the fins 230A, 230B or the fins 230C, 230D. Sidewalls of the neighboring fins 230B, 230C define boundaries of the passing word line area 250, with the portion 240 of the second material 235 vertically extending (e.g., vertically oriented) between the neighboring fins 230B, 230C and into the passing word line area 250. As depicted in FIG. 2A, areas between other neighboring fins (e.g., fins 230A and 230B or between fins 230C and 230D) may define boundaries of the active word line area 260. Sidewalls of the first material 210 and/or of the portion 240 of the second material 235 may be tapered.

The fins 230 may be formed of and include a semiconductive material (e.g., a silicon material) and are configured to function as a channel of a memory cell. The fins 230 may individually comprise the same material composition as the base material. In some embodiments, at least a portion of the fins 230 comprises one or more dopants.

The first material 210 of the STI structures 210′ may be selected to include a material that exhibits an etch selectivity relative to the second material 235, so that when the microelectronic structures 100A-100D are subjected to removal processing acts (e.g., etching acts), the second material 235 may be removed at a lower rate (e.g., a lower etch rate) than the first material 210 of the STI structures 210′. The etch selectivity may be achieved by selecting the first material 210 and the second material 235 to be different material compositions (e.g., chemical compositions) or the etch selectivity may be achieved by using a single material (e.g., a single chemical composition) having different densities. For example, the second material 235 may exhibit a higher density than the first material 210 of the STI structures 210′. The first material 210 may be an insulative material. By way of non-limiting examples, the first material 210 may be formed of and include a silicon oxide material or a silicon nitride material. The second material 235 may be formed of and include the other of the silicon oxide material or the silicon nitride material, or another material exhibiting the desired etch selectivity. In some embodiments, the second material 235 comprises silicon oxide or silicon nitride with the first material 210 comprising the other of silicon oxide or silicon nitride. In other embodiments, the second material 235 comprises a so-called “high quality” silicon oxide while the first material 210 comprises silicon oxide, with the different densities of the silicon oxide providing the etch selectivity. However, the disclosure is not so limited and other materials, or combinations of materials, may be used as the first material and/or the second material.

The STI structures 210′ may be formed by forming openings in the passing word line area 250 and the active word line areas 260, the openings extending vertically in the base material, followed by forming the first material within the openings. The first material 210 may substantially completely fill the openings in the active word line areas 260, forming the STI structures 210′, while the openings in the passing word line area 250 are partially filled with the first material 210. The remaining portions of the openings in the passing word line area 250 may be filled with the second material 235, which is also formed over the first material 210 and the fins 230, producing the vertically oriented portion 240 of the second material 235. The vertically oriented portion 240 of the second material 235 extends into the passing word line area 250. The portion of the second material 235 adjacent (e.g., over) the first material 210 and the fins 230 is sacrificial (e.g., subsequently removed) while at least a portion of the vertically oriented portion 240 remains in the microelectronic structure 100 (see FIGS. 2D and 2F).

Following formation of the second material 235, a removal act (e.g., a wet etch, a dry etch) is conducted to remove portions of the first material 210 and the second material 235, as shown in FIG. 2B, to form openings 215. As a result of the different etch selectivities of the first material 210 and the second material 235, the first material 210 may be removed at a faster rate than the second material 235, resulting in deeper openings in the active word line areas 260 than in the passing word line area 250. In addition, portions of the second material 235 overlying the first material 210 and the fins 230 may be substantially completely removed while at least a portion of the vertically oriented portion 240 remains in the passing word line area 250. An upper surface of the vertically oriented portion 240 of the second material 235 may be recessed relative to the upper surfaces of the fins 230. Upper surfaces of the first material 210A, 210D in the active word line areas 260 may be recessed relative to upper surfaces of the first material 210B, 210C in the passing word line area 250. In other words, a depth D1 of the openings 215 in the active word line area 260 is relatively greater than a depth D2 of the openings 215 in the passing word line area 250. The depth D1 extends, for example, from an upper surface of the fins 230A, 230D to an upper surface of the first material 210A, 210D. The depth D2 extends, for example, from an upper surface of the fins 230B, 230C to an upper surface of the first material 210B, 210C. The etch process used to form the openings 215 in the active word line areas 260 and the passing word line area 250 may, for example, be a dry etch process. The type of etch process (e.g., etch chemistry, etch conditions) used, in combination with the materials selected for the first material 210 and the second material 235, may enhance the relative difference in material etch rate of first material 210 and the second material 235.

As shown in FIG. 2C, a gate dielectric material 270 (e.g., a gate oxide material) may be formed in the openings 215. The gate dielectric material 270 may extend over exposed surfaces of the first material 210, the fins 230, and the remaining vertically oriented portion 240 of the second material 235, directly contacting the first material 210, the fins 230, and the vertically oriented portion 240. The gate dielectric material 270 may be conformally formed in the openings 215 and extend across and substantially cover the first material 210, the fins 230, and the vertically oriented portion 240 of the second material 235. The gate dielectric material 270 may substantially fill the openings 215 between the fins 230 and the vertically oriented portion 240 of the second material 235 in the passing word line area 250. The gate dielectric material 270 may be formed in only a portion of the openings 215 in the active word line areas 260 (e.g., between neighboring fins 230A, 230B and between neighboring fins 230C, 230D). The gate dielectric material 270 may be formed of and include one or more of silicon dioxide, silicon oxynitride, phosphosilicate glass, borosilicate glass, borophosphosilicate glass (BPSG), fluorosilicate glass, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), another gate dielectric material, a dielectric carbon nitride material (e.g., silicon carbon nitride (SiCN)), a dielectric carboxynitride material (e.g., silicon carboxynitride (SiOCN)), or combinations thereof. In some embodiments, the gate dielectric material 270 comprises silicon dioxide. The gate dielectric material 270 may comprise a material composition (e.g., chemical composition) that differs from that of the first material of the first material 210 or the second material 235.

Following formation of the gate dielectric material 270, a word line material 280 is formed in remaining portions of the openings 215 in the active word line areas 260 (e.g., between neighboring fins 230A, 230B and between neighboring fins 230C, 230D), as shown in FIG. 2D. The word line material 280 is also formed over the second material 235 and the fins 230. The word line material 280 extends across and substantially covers the gate dielectric material 270, the STI structures 210′, and the fins 230. The word line material 280 is in direct contact with the gate dielectric material 270. Since the word line material 280 is formed in only some of the openings 215, an as-formed thickness of the word line material 280 is not substantially uniform in the microelectronic structure 100D. Rather, a lower surface (e.g., a lowermost surface) of the word line material 280 is located at a different depth (e.g., a deeper depth) in the active word line area 260 than in the passing word line area 250. The word line material 280 may be formed of and include a conductive material. In some embodiments, the word line material 280 comprises titanium nitride. In other embodiments, the word line material 280 comprises polysilicon.

Since the openings 215 are formed to different depths due to the etch selectivity difference between the first material 210 and the second material 235 during the removal act shown in FIG. 2B, portions of the word line material 280 extend vertically between adjacent fins 230, such as between fins 230A, 230B and between fins 230C, 230D. In other words, the vertically extending portions of the word line material 280 intervene between the fins 230A, 230B and between the fins 230C, 230D in the active word line areas 260. In the passing word line area 250, the word line material 280 does not substantially intervene between the fin 230B and the vertically oriented portion 240 of the second material 235 or between the vertically oriented portion 240 of the second material 235 and the fin 230C. Since the gate dielectric material 270 substantially fills the openings 215 in the passing word line area 250, little or no word line material 280 is present between the fin 230B, the vertically oriented portion 240 of the second material 235, and the fin 230C.

The word line material 280 in FIG. 2D corresponds to the word lines 120 of FIG. 1. The word lines 120 are asymmetric in that a lower surface (e.g., a lowermost surface) of the word lines 120 is not planar across the active word line area 260 and the passing word line area 250. Rather, the lower surface of the word lines 120 extends to different depths in the active word line area 260 relative to the passing word line area 250 while an upper surface (e.g., an uppermost surface) of the word lines 120 may be substantially planar. As shown in FIG. 2E, the word line material 280 of the word lines 120 may surround an upper portion of some of the fins 230 (e.g., fins 230A, 230D), with the gate dielectric material 270 intervening between the fins 230A, 230D and the word lines 120. For example, the upper portions of fins 230A, 230D may be substantially completely surrounded by the word line material 280 of the word lines 120. An upper portion of other fins 230 (e.g., fins 230B, 230C) are not substantially completely surrounded by the word line material 280 of the word lines 120. For example, the word line material 280 of the word lines 120 may be present on the upper portions of the fins 230B, 230C in the active word line area 260 and the gate dielectric material 270 may be present on the upper portions of the fins 230B, 230C in the passing word line area 250. The word lines 120, therefore, do not exhibit a substantially uniform, as-formed thickness in the microelectronic structures 100D. Since the lower surface of the word lines 120 in the active word line area 260 is deeper than the lower surface of the word lines 120 in the passing word line area 250, the word lines 120 are asymmetric. In contrast, word lines of conventional microelectronic devices at a similar processing stage have a substantially uniform, as-formed thickness. In addition, the word lines 120 according to embodiments of the disclosure do not substantially completely surround all of the fins 230, which results in asymmetry of the word lines 120. For example, fins 230B, 230C are not substantially completely surrounded by the word line material 280 of the word lines 120.

Following formation of the word line material 280, conventional processing acts are conducted to form the word lines 120 from the word line material 280, with the word lines 120 exhibiting different depths in the active word line areas 260 than in the passing word line areas 250. A depth D3 of the word lines 120 in the active word line area 260 is relatively greater than a depth D4 of the word lines 120 in the passing word line area 250, as shown in FIG. 2D. The depth D3 extends from an upper surface of the gate dielectric material 270 over the fins 230A, 230D to an upper surface of the gate dielectric material 270 over the STI structure 210′, as shown by dashed lines. The depth D4 extends from an upper surface of the gate dielectric material 270 over the fins 230B, 230C to an upper surface of the gate dielectric material 270 between the fins 230B, 230C and the vertically oriented portion 240, as shown by dashed lines. The depth D3 of the word lines 120 in the active word line areas 260 may be within a range from about 40 nm to about 90 nm, such as from about 40 nm to about 50 nm, from about 50 nm to about 70 nm, or from about 70 nm to about 90 nm. The depth D4 of the word lines 120 in the passing word line area 250 may be within a range from about 5 nm to about 35 nm, such as from about 5 nm to about 15 nm, from about 15 nm to about 25 nm, or from about 25 nm to about 35 nm. However, the disclosure is not so limited and the depths D3 and D4 may be different than those described. Since the depths D3 and D4 are different, the word lines 120 exhibit, in cross-section, a relatively deeper AWL depth and a relatively shallower PWL depth.

As best shown in FIGS. 2D and 2E, the word lines 120 of the microelectronic structure 100, 100D are asymmetric in that the depths of a lower surface of the word lines 120 in the active word line areas 260 and the passing word line areas 250 are different. The word lines 120 extend relatively deeper in the active word line areas 260 than in the passing word line areas 250. The materials surrounding the fins 230 also differ, which contributes to the asymmetry. The upper portions of the fins 230A, 230D are surrounded by the gate dielectric material 270 and the word line material 280 of the word lines 120, while the upper portions of the fins 230B, 230C are surrounded by the gate dielectric material 270. The word line material 280 does not surround both surfaces of the fins 230B, 230C since the gate dielectric material 270 fills in the openings 215 proximal to the vertically oriented portion 240 of the second material 235.

Forming the word lines 120 that extend the greater depth (e.g., depth D3) in the active word line area 260 than the depth D4 in the passing word line area 250, as described above, improves row hammer performance of electronic devices containing the microelectronic structures 100, 100D. Since the PWL depth D4 is shallow relative to the AWL depth D3, the microelectronic structures 100, 100D exhibit improved row hammer performance properties compared to conventional microelectronic structures. The shallower depth D4 in the passing word line area 250 increases the row hammer properties without negatively impacting drive current of the microelectronic structure 100. Any changes to drive current in the microelectronic structures 100, 100D are minimal since the AWL depth D3 is substantially the same as in conventional microelectronic structures. The different depths D3 and D4 of the word lines 120 may also reduce leakage of charge during the off state compared to that in conventional microelectronic structures. The asymmetric word lines 120 according to embodiments of the disclosure in the electronic device may reduce leakage from a storage device (e.g., a capacitor) during the “off” state when an associated memory cell is not selected. The reduction in the charge leakage from the storage device may improve performance of the electronic device, such as by increasing the amount of time between refresh operations of the memory cells associated with the storage device. Electronic devices including the asymmetric word lines 120 formed to the deeper active word line depth than the passing word line depth results in improved row hammer performance, such as reducing the row hammer performance by five times compared to conventional electronic devices. This is in contrast to conventional processes for forming microelectronic devices, where the active word line depth and the passing word line depth are substantially equal or the passing word line depth is deeper than that of the active word line depth.

FIG. 2F illustrates the microelectronic structure 100F including the AWLs 290 and the PWLs 295. The PWLs 295 and the AWLs 290 may be formed of a conductive material. The AWLs 290 and the PWLs 295 may be formed by conventional techniques. Although only FIG. 2F illustrates the AWLs 290 and the PWLs 295, the AWLs 290 and the PWLs 295 may be formed and present at any processing stage shown in FIGS. 2A-2D. The AWLs 290 and the PWLs 295 are omitted for simplicity and convenience in FIGS. 2A-2D. The AWLs 290 and the PWLs 295 may be electrically coupled to the word lines 120, with the PWLs 295 proximal to the vertically oriented portion 240 and the AWLs 290 distal to the vertically oriented portion 240. The AWLs 290 and the PWLs 295 are between the fins 230. As shown in FIG. 2F, the AWLs 290 are between the fins 230A, 230B and between the fins 230C, 230D. The PWLs 295 are between the fins 230B, 230C. The STI structures 210′ are adjacent to the AWLs 290 and the PWLs 295, providing isolation from the fins 230. The PWLs 295 and the AWLs 290 extend parallel to the y-axis and substantially horizontally perpendicular to the word lines 120.

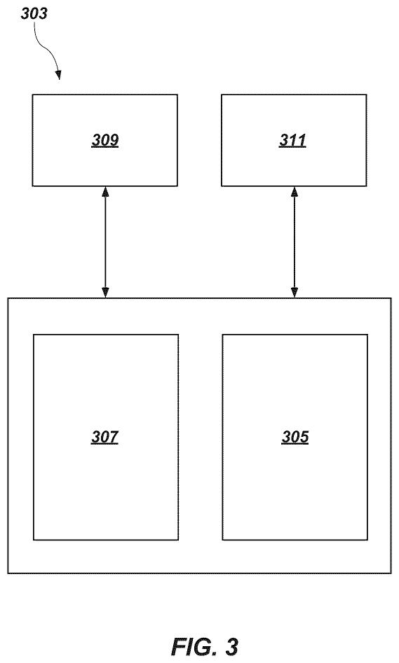

Apparatuses including, for example, the microelectronic structures 100 may be used in embodiments of electronic systems of the disclosure. The microelectronic structures 100 may include asymmetric word lines 120 that exhibit the depth D3 in the active word line area 260, which is greater than the depth D4 of the asymmetric word lines 120 in the passing word line area 250 as described above. For example, FIG. 3 is a block diagram of an electronic system 303, in accordance with embodiments of the disclosure. The electronic system 303 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 303 includes at least one memory device 305. The memory device 305 may include, for example, an embodiment of an apparatus (e.g., the microelectronic structure 100) previously described with reference to FIG. 1 and FIGS. 2A through 2F including the asymmetric word lines 120.

The electronic system 303 may further include at least one electronic signal processor device 307 (often referred to as a “microprocessor”). The electronic signal processor device 307 may, optionally, include an embodiment of an apparatus (e.g., the microelectronic structure 100) previously described with reference to FIG. 1 and FIGS. 2A through 2F. The electronic system 303 may further include one or more input devices 309 for inputting information into the electronic system 303 by a user, such as, for example, a mouse or other pointing device, a keyboard, a touchpad, a button, or a control panel. The electronic system 303 may further include one or more output devices 311 for outputting information (e.g., visual or audio output) to a user such as, for example, a monitor, a display, a printer, an audio output jack, a speaker, etc. In some embodiments, the input device 309 and the output device 311 may comprise a single touchscreen device that can be used both to input information to the electronic system 303 and to output visual information to a user. The input device 309 and the output device 311 may communicate electrically with one or more of the memory device 305 and the electronic signal processor device 307.

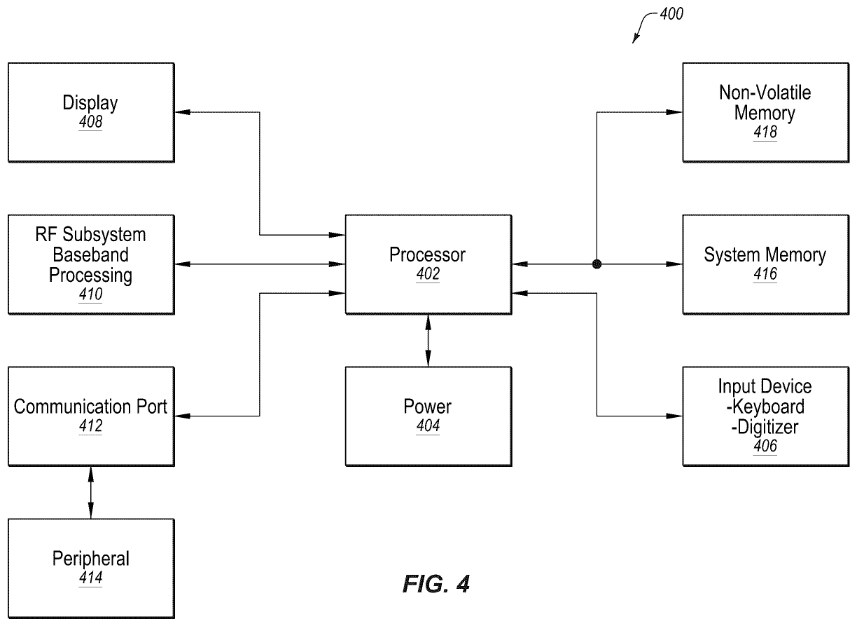

With reference to FIG. 4, depicted is a processor-based system 400. The processor-based system 400 may include various apparatuses (e.g., the microelectronic structures 100) manufactured in accordance with embodiments of the disclosure. The processor-based system 400 may be any of a variety of types such as a computer, pager, cellular phone, personal organizer, control circuit, or other apparatus. The processor-based system 400 may include one or more processors 402, such as a microprocessor, to control the processing of system functions and requests in the processor-based system 400. The processor 402 and other subcomponents of the processor-based system 400 may include apparatuses (e.g., the microelectronic structures 100) manufactured in accordance with embodiments of the disclosure.

The processor-based system 400 may include a power supply 404 in operable communication with the processor 402. For example, if the processor-based system 400 is a portable system, the power supply 404 may include one or more of a fuel cell, a power scavenging device, permanent batteries, replaceable batteries, and rechargeable batteries. The power supply 404 may also include an AC adapter; therefore, the processor-based system 400 may be plugged into a wall outlet, for example. The power supply 404 may also include a DC adapter such that the processor-based system 400 may be plugged into a vehicle cigarette lighter or a vehicle power port, for example.

Various other devices may be coupled to the processor 402 depending on the functions that the processor-based system 400 performs. For example, a user interface 406 may be coupled to the processor 402. The user interface 406 may include input devices such as buttons, switches, a keyboard, a light pen, a mouse, a digitizer and stylus, a touch screen, a voice recognition system, a microphone, or a combination thereof. A display 408 may also be coupled to the processor 402. The display 408 may include an LCD display, an SED display, a CRT display, a DLP display, a plasma display, an OLED display, an LED display, a three-dimensional projection, an audio display, or a combination thereof. Furthermore, an RF sub-system/baseband processor 410 may also be coupled to the processor 402. The RF sub-system/baseband processor 410 may include an antenna that is coupled to an RF receiver and to an RF transmitter (not shown). A communication port 412, or more than one communication port 412, may also be coupled to the processor 402. The communication port 412 may be adapted to be coupled to one or more peripheral devices 414, such as a modem, a printer, a computer, a scanner, or a camera, or to a network, such as a local area network, remote area network, intranet, or the Internet, for example.

The processor 402 may control the processor-based system 400 by implementing software programs stored in the memory. The software programs may include an operating system, database software, drafting software, word processing software, media editing software, or media playing software, for example. The memory is operably coupled to the processor 402 to store and facilitate execution of various programs. For example, the processor 402 may be coupled to system memory 416, which may include one or more of spin torque transfer magnetic random-access memory (STT-MRAM), magnetic random-access memory (MRAM), dynamic random-access memory (DRAM), static random-access memory (SRAM), racetrack memory, and other known memory types. The system memory 416 may include volatile memory, non-volatile memory, or a combination thereof. The system memory 416 is typically large so that it can store dynamically loaded applications and data. In some embodiments, the system memory 416 may include apparatuses (e.g., the microelectronic structures 100) described above.

The processor 402 may also be coupled to non-volatile memory 418, which is not to suggest that system memory 416 is necessarily volatile. The non-volatile memory 418 may include one or more of STT-MRAM, MRAM, read-only memory (ROM) such as an EPROM, resistive read-only memory (RROM), and flash memory to be used in conjunction with the system memory 416. The size of the non-volatile memory 418 is typically selected to be just large enough to store any necessary operating system, application programs, and fixed data. Additionally, the non-volatile memory 418 may include a high-capacity memory such as disk drive memory, such as a hybrid-drive including resistive memory or other types of non-volatile solid-state memory, for example. The non-volatile memory 418 may include apparatuses (e.g., the microelectronic structures 100) described above.

Accordingly, a microelectronic device is disclosed and comprises a memory cell array comprising memory cells. At least one of the memory cells comprises active areas and shallow trench isolation structures adjacent to a base material and fins extending from the base material and adjacent to the active areas. A gate dielectric material is between adjacent fins and a word line material is over the gate dielectric material. The word line material extends different depths between adjacent fins to form an asymmetric word line. The asymmetric word line extends a first depth between some adjacent fins and extends a second depth between other adjacent fins. Active word lines and passing word lines are adjacent to the asymmetric word line.

Accordingly, an electronic system is disclosed and comprises an input device, an output device, and a processor device operably coupled to the input device and the output device. Memory devices are operably coupled to the processor device and comprise one or more microelectronic devices, which comprise digit lines, asymmetric word lines operably coupled to the digit lines, and memory cells operably coupled to the digit lines and the asymmetric word lines. The one or more memory cells comprise fins of a base material over active areas of the one or more microelectronic devices. A first portion of the asymmetric word lines extends between adjacent fins to a first depth and a second, different portion of the asymmetric word lines extends between additional adjacent fins to a second depth. The first depth is greater than the second depth. A gate dielectric material is between the fins and the asymmetric word lines. Active word lines are laterally adjacent to passing word lines and separated therefrom by isolation structures. The active word lines are adjacent to the first portion of the asymmetric word lines and the passing word lines are adjacent to the second portion of the asymmetric word lines.

Accordingly, a method of forming a microelectronic device is disclosed and comprises forming fins of a base material extending perpendicular to the base material and adjacent to active areas of a microelectronic device. A first material is formed over and between the fins and a second material is formed over the first material. The first material is selectively etchable relative to the second material. A portion of the first material and the second material is removed to form openings between adjacent fins, some of the openings in an active word line area and exhibiting a first depth and other of the openings in a passing word line area and exhibiting a second depth. A gate dielectric material is formed over the fins and the first material and a word line material is formed over the gate dielectric material. The word line material extends the first depth between some of the fins and extends the second depth between other of the fins.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a memory cell array comprising memory cells, at least one of the memory cells comprising:
active areas and shallow trench isolation structures adjacent to a base material;
fins extending from the base material and adjacent to the active areas;
a gate dielectric material between adjacent fins;
a word line material over the gate dielectric material, the word line material extending different depths between adjacent fins to form an asymmetric word line, the asymmetric word line extending a first depth between some adjacent fins and a second depth between other adjacent fins;
active word lines adjacent to the asymmetric word line; and
passing word lines adjacent to the asymmetric word line.

2. The microelectronic device of claim 1, wherein the first depth of the asymmetric word line is greater than the second depth of the asymmetric word line.

3. The microelectronic device of claim 1, wherein the microelectronic device comprises a passing word line area between the other adjacent fins.

4. The microelectronic device of claim 3, further comprising a vertically oriented portion of an insulative material between the other adjacent fins in the passing word line area.

5. The microelectronic device of claim 3, wherein the microelectronic device comprises an active word line area laterally adjacent to the passing word line area and between the some adjacent fins.

6. The microelectronic device of claim 5, wherein the asymmetric word line extends deeper into the active word line area than into the passing word line area.

7. The microelectronic device of claim 1, wherein the active word lines are vertically adjacent to the asymmetric word line extending the first depth.

8. The microelectronic device of claim 1, wherein the passing word lines are vertically adjacent to the asymmetric word line extending the second depth.

9. An electronic system comprising:
an input device, an output device, and a processor device operably coupled to the input device and the output device; and
memory devices operably coupled to the processor device and comprising one or more microelectronic devices, the one or more microelectronic devices comprising:
digit lines, asymmetric word lines operably coupled to the digit lines, and memory cells operably coupled to the digit lines and the asymmetric word lines, one or more of the memory cells comprising:
fins of a base material over active areas of the one or more microelectronic devices, a first portion of the asymmetric word lines extending between adjacent fins to a first depth and a second, different portion of the asymmetric word lines extending between additional adjacent fins to a second depth, the first depth greater than the second depth;
a gate dielectric material between the fins and the asymmetric word lines; and
active word lines laterally adjacent to passing word lines and separated therefrom by isolation structures, the active word lines adjacent to the first portion of the asymmetric word lines and the passing word lines adjacent to the second, different portion of the asymmetric word lines.

10. The electronic system of claim 9, wherein the isolation structures are laterally adjacent to the fins.

11. The electronic system of claim 9, wherein the word lines and the gate dielectric material substantially surround an upper portion of some of the fins.

12. The electronic system of claim 9, wherein the gate dielectric material substantially surrounds an upper portion of other of the fins.

13. A method of forming a microelectronic device, comprising:
forming fins of a base material extending perpendicular to the base material and adjacent to active areas of a microelectronic device;
forming a first material over and between the fins;
forming a second material over the first material, the first material selectively etchable relative to the second material;
removing a portion of the first material and the second material to form openings between adjacent fins, some of the openings in an active word line area and exhibiting a first depth and other of the openings in a passing word line area and exhibiting a second depth;
forming a gate dielectric material over the fins and the first material; and
forming a word line material over the gate dielectric material, the word line material extending the first depth between some of the fins and extending the second depth between other of the fins.

14. The method of claim 13, further comprising forming active word lines and passing word lines between the fins.

15. The method of claim 13, wherein removing a portion of the first material and the second material comprises removing the second material so that only a vertically oriented portion of the second material remains between adjacent fins in the passing word line area.

16. The method of claim 13, wherein removing a portion of the first material and the second material comprises forming the openings in the active word line area extending deeper than the openings in the passing word line area.

17. The method of claim 13, wherein forming a gate dielectric material over the fins and the first material comprises conformally forming the gate dielectric material in the openings.

18. The method of claim 16, wherein conformally forming the gate dielectric material in the openings comprises substantially completely filling the openings in the passing word line area with the gate dielectric material and partially filling the openings in the active word line area with the gate dielectric material.

19. The method of claim 17, wherein forming a word line material over the gate dielectric material comprises forming the word line material in remaining openings in the active word line area.

20. The method of claim 17, wherein forming a word line material over the gate dielectric material comprises forming the word line material extending the first depth in the active word line area and extending the second depth in the passing word line area.
